(19) United States
(12) Patent Application Publication
(10) Pub. No.: US 2026/0214354 A1
(43) Pub. Date: Jul. 23, 2026

(54) DEPTH SENSOR AND ELECTRONIC DEVICE INCLUDING DEPTH SENSOR

(71) Applicant: Samsung Electronics Co., LTD., Suwon-si (KR)

(72) Inventors: SUNGHYUCK CHO, Suwon-si (KR); Bumsuk kim, Suwon-si (KR); Sungyoung Seo, Suwon-si (KR); Minhee Son, Suwon-si (KR); Seunghyun Lee, Suwon-si (KR); Younggu Jin, Suwon-si (KR)

(73) Assignee: Samsung Electronics Co., LTD., Suwon-si (KR)

(21) Appl. No.: 19/419,928

(22) Filed: Dec. 15, 2025

(30) Foreign Application Priority Data
Jan. 23, 2025 (KR) 10-2025-0010549

(51) Int. Cl. H04N 25/705; H10F 39/00

(52) U.S. Cl. CPC H04N 25/705; H10F 39/807; H10F 39/811

(57) ABSTRACT

Provided is a depth sensor including a substrate including a first surface and a second surface that are opposite to each other, a first pixel including a first photoelectric conversion element in the substrate, and a second pixel adjacent to the first pixel, the second pixel including a second photoelectric conversion element in the substrate, wherein the first pixel includes a first tab and a second tab that are connected to the first photoelectric conversion element, wherein the second pixel includes a third tab connected to the second photoelectric conversion element, wherein the second tab includes a first floating diffusion region, wherein the third tab includes a second floating diffusion region, and wherein a connection portion adjacent to the first surface of the substrate is between the first floating diffusion region and the second floating diffusion region.

### CROSS-REFERENCE TO RELATED APPLICATION

This application claims priority to Korean Patent Application No. 10-2025-0010549 filed with the Korean Intellectual Property Office on January 23, 2025, the disclosure of which is incorporated herein in its entirety by reference.

### BACKGROUND

### Field

Embodiments of the present disclosure relate to a depth sensor and an electronic device including the depth sensor.

### Description of Related Art

An electronic device typically includes sensors that perform various functions, such as calculating a distance between the image sensor and an object or recognizing an object using the captured image.

In the semiconductor industry, there is an increasing demand for higher-capacity, thinner, and more compact semiconductor devices and electronic products utilizing them.

As semiconductor devices become higher-capacity, thinner, and more compact, the components equipped in electronic devices, such as depth sensors, are also becoming high-capacity, thinner, and more compact.

### SUMMARY

One or more embodiments provide a depth sensor and an electronic device including the same having a reduced pixel size while maintaining the operating characteristics of the sensor.

However, objects which embodiments attempt to achieve are not limited to the above-mentioned object, and can be variously expanded without departing from the technical spirit and scope of the embodiments.

According to an aspect of one or more embodiments, there is provided a depth sensor including a substrate including a first surface and a second surface that are opposite to each other, a first pixel including a first photoelectric conversion element in the substrate, and a second pixel adjacent to the first pixel, the second pixel including a second photoelectric conversion element in the substrate, wherein the first pixel includes a first tab and a second tab that are connected to the first photoelectric conversion element, wherein the second pixel includes a third tab connected to the second photoelectric conversion element, wherein the second tab includes a first floating diffusion region, wherein the third tab includes a second floating diffusion region, and wherein a connection portion adjacent to the first surface of the substrate is between the first floating diffusion region and the second floating diffusion region.

According to another aspect of one or more embodiments, there is provided a depth sensor including a substrate including a first surface and a second surface that are opposite to each other, a first pixel including a first photoelectric conversion element in the substrate, a second pixel adjacent to the first pixel, the second pixel including a second photoelectric conversion element in the substrate, a photoelectric conversion element isolation pattern in the substrate and between the first photoelectric conversion element and the second photoelectric conversion element, and a pad portion connected to the photoelectric conversion element isolation pattern, wherein the first pixel includes a first tab and a second tab that are connected to the first photoelectric conversion element, wherein the second pixel includes a third tab connected to the second photoelectric conversion element, and wherein the first tab and the third tab share a floating diffusion region.

According to still another aspect of one or more embodiments, there is provided an electronic device including a camera including a depth sensor, and an application processor configured to drive the camera, wherein the depth sensor includes a substrate including a first surface and a second surface that are opposite to each other, a first pixel including a first photoelectric conversion element within the substrate, and a second pixel adjacent to the first pixel, the second pixel including a second photoelectric conversion element within the substrate, wherein the first pixel includes a first tab and a second tab connected to the first photoelectric conversion element, wherein the second pixel includes a third tab connected to the second photoelectric conversion element, wherein the second tab includes a first floating diffusion region, wherein the third tab includes a second floating diffusion region, and wherein the first floating diffusion region and the second floating diffusion region are connected to each other.

### BRIEF DESCRIPTION OF DRAWINGS

Embodiments will be more clearly understood from the following detailed description taken in conjunction with the accompanying drawings in which:

FIG. 1 is a block diagram of a sensing system according to one or more embodiments;

FIG. 2 is a plan view showing a part of a pixel array of a sensing system according to one or more embodiments;

FIG. 3 is an equivalent circuit diagram of a single pixel of the sensing system according to one or more embodiments;

FIG. 4 is a timing diagram for explaining an operation of a depth sensor according to one or more embodiments;

FIG. 5 is a plan view showing a portion of a pixel array of a depth sensor according to one or more embodiments;

FIG. 6 is a sectional view taken along line I-I' of FIG. 5;

FIG. 7 is a sectional view taken along II-II' of FIG. 5;

FIG. 8 is a plan view showing a portion of a pixel array of a depth sensor according to one or more other embodiments;

FIG. 9 is a cross-sectional view taken along line II-II' of FIG. 8;

FIG. 10 is a plan view showing a part of a pixel array of a depth sensor according to one or more other embodiments;

FIG. 11 is a sectional view taken along line II-II' of FIG. 10;

FIG. 12 is a sectional view taken along the line III-III' of FIG. 10;

FIG. 13 is an equivalent circuit diagram of a single pixel of a depth sensor according to one or more embodiments;

FIG. 14 is a plan view showing a part of a pixel array of a depth sensor according to one or more embodiments;

FIG. 15 is a plan view showing a part of a pixel array of a depth sensor according to one or more embodiments;

FIG. 16 is a plan view showing a part of a pixel array of a depth sensor according to one or more embodiments;

FIG. 17 is a plan view showing a part of a pixel array of a depth sensor according to one or more embodiments;

FIG. 18 is a block diagram of an electronic device including a depth sensor according to one or more embodiments; and

FIG. 19 is a block diagram of a camera module of the electronic device in FIG. 18.

### DETAILED DESCRIPTION

In the following detailed description, only certain embodiments have been shown and described, simply by way of illustration. This disclosure can be variously implemented and is not limited to the following embodiments.

The drawings and description are to be regarded as illustrative in nature and not restrictive. Like reference numerals designate like elements throughout the specification.

Further, the accompanying drawings are provided to help understand embodiments disclosed in the present specification, and the technical spirit disclosed in the present specification is not limited by the accompanying drawings, and it will be appreciated that this disclosure includes all of the modifications, equivalent matters, and substitutes included in the spirit and the technical scope of this disclosure.

In addition, the size and thickness of each configuration shown in the drawings are arbitrarily shown for understanding and ease of description, but this disclosure is not limited thereto. In the drawings, the thickness of layers, films, panels, regions, etc., are exaggerated for clarity. Further, in the drawings, for understanding and ease of description, the thickness of some layers and areas is exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, in the entire specification, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

Further, throughout the specification, when it is referred to as “connected”, this does not only mean that two or more constituent elements are directly connected, but may mean that two or more constituent elements are indirectly connected through another constituent element, are physically connected, electrically connected, or are integrated even though two or more constituent elements are referred as different names depending on a location and a function.

Hereinafter, various embodiments and modifications will be described in detail with reference to the drawings.

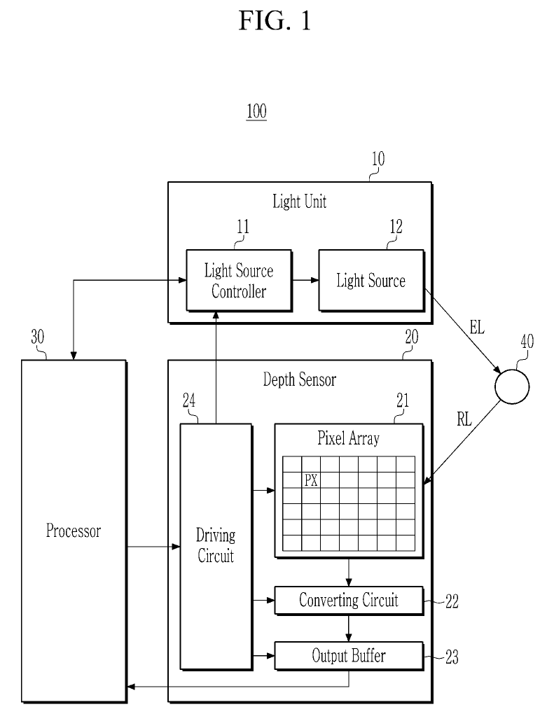

Referring to FIG. 1, the sensing system 100 according to one or more embodiments will be described. FIG. 1 is a block diagram of the sensing system 100 according to one or more embodiments.

Referring to FIG. 1, the sensing system 100 according to one or more embodiments may include a light unit 10, a depth sensor 20, and a processor 30.

The sensing system 100 may be implemented in any of various electronic devices, such as a digital camera, a smart phone, a tablet personal computer (PC), and a wearable device. The sensing system 100 may be used in various systems for recognition of surroundings, such as autonomous driving systems.

The sensing system 100 may be embodied as one of an integrated circuit (IC), a system on chip (SoC), etc.

The light unit 10 may include a light source controller 11 and a light source 12.

The light source controller 11 controls the light source 12 under control of the depth sensor 20 or the processor 30. The light source controller 11 modulates a light signal EL emitted or output from the light source 12. The light source 12 emits the light signal EL modulated by the light source controller 11. For example, the modulated light signal EL may have a form of a pulse wave or a sinusoidal wave, and the light signal EL may be infrared light, microwave radiation, or visible light.

The light source 12 includes, for example, at least one of an light emitting diode (LED), a laser diode (LD), or an organic LED (OLED).

The depth sensor 20 detects a light signal RL reflected from an object 40. The depth sensor 20 detects a distance between the object 40 and the image sensing system 100 based on the reflected light signal RL.

The depth sensor 20 includes a pixel array 21, a conversion circuit 22, an output buffer 23, and a driving circuit 24.

The depth sensor 20 may be referred to as a time of flight (TOF) sensor.

The pixel array 21 includes a plurality of pixels PX. Each pixel PX generates an analog signal based on the light signal RL reflected from the object 40. The analog signal includes pixel signals that correspond to each of the pixels PX. Due to a distance between the image sensing system 100 and the object 40, a time at which the light signal RL is incident to the pixel array 21 is later than a time at which the light signal EL output from the light source 12 is directly incident to the pixel array 21. Therefore, a difference between a time at which the light signal RL is incident to the pixel array 21 and a time at which the light signal EL is directly incident to the pixel array 21 occurs. The distance between the object 40 and the image sensing system 100 can be calculated (obtained) based on the difference between the time at which the light signal RL is incident to the pixel array 21 and the time at which the light signal EL is directly incident to the pixel array 21 occurs. The pixel array 21 is controlled based on drive signals received from the driving circuit 24.

The conversion circuit 22 converts an analog signal generated by the pixel array 21 into a digital signal. The conversion circuit 22 may convert the analog signal into the digital signal based on the control signals received from the driving circuit 24. For example, the conversion circuit 22 performs a correlated double sampling (CDS) operation on the analog signal, and removes noise from the analog signal. The conversion circuit 22 constructs depth data using the digital signal. The depth data may be referred to as distance data.

The output buffer 23 stores the depth data generated by the conversion circuit 22. The output buffer 23 outputs the digital signal to the processor 30.

The driving circuit 24 controls the pixel array 21, the conversion circuit 22, and the output buffer 23. The driving circuit 24 may generate a clock signal and a timing control signal that operate each of the pixel array 21, the conversion circuit 22, and the output buffer 23. The clock signal and the timing control signal are provided to the light source controller 11.

The processor 30 can perform control operations to control the sensing system 100 and calculation operations to calculate (obtain) various data. The processor 30 may control the light unit 10 such that the light source 12 outputs the light signal EL. The processor 30 controls the depth sensor 20 to sense the light signal RL reflected from the object 40 and to generate the depth data based on the sensed light signal RL. The processor 30 may include an image signal processor that processes the depth data received from the output buffer 23. The image signal processor calculates (obtains) the distance between the object 40 and the image sensing system 100, which is a TOF value, based on the depth data. For example, the processor 30 calculates (obtains) a difference between a time at which the output light signal EL is directly incident to the pixel array 21 and a time at which the reflected light signal RL is incident thereto, based on the depth data, and calculates the TOF value based on the difference. The processor 30 determines a distance to the object, a shape thereof, and a movement speed thereof, based on the TOF value. The processor 30 is disposed within the depth sensor 20.

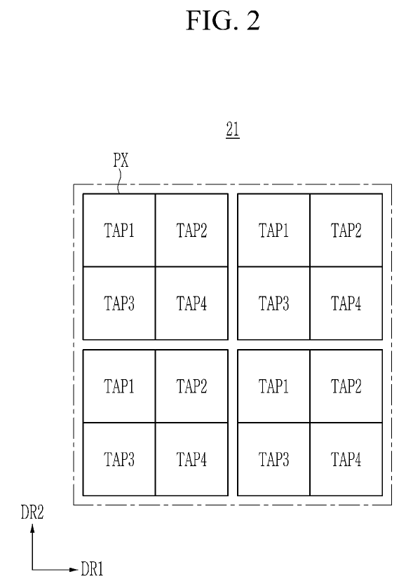

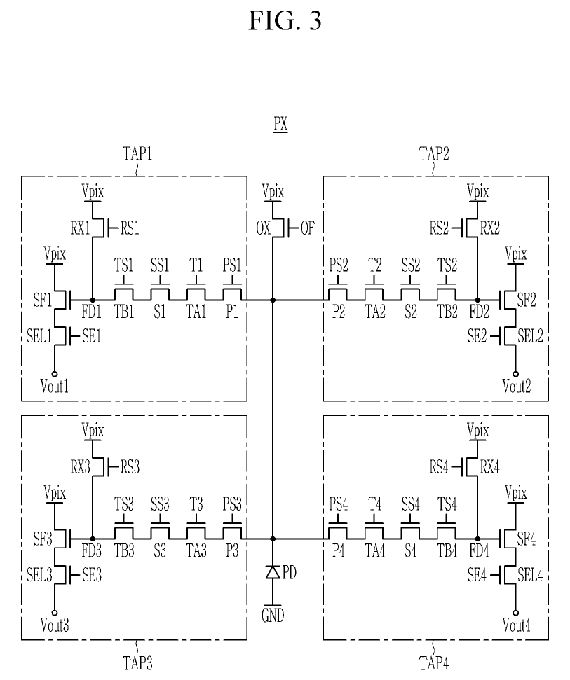

Referring to FIG. 2 and FIG. 3, a pixel array of the sensing system 10000 will be described. FIG. 2 is a plan view showing a part of a pixel array of a sensing system according to one or more embodiments and FIG. 3 is an equivalent circuit diagram of a single pixel of the sensing system according to one or more embodiments.

Referring to FIGS. 2 and 3, the pixel array 21 may include a plurality of pixels PX.

The plurality of pixels PX may be arranged along a first direction DR1 and a second direction DR2.

The pixel PX may have a 4-tap structure. The pixel PX may include a photoelectric conversion element PD, a first tap TAP1, a second tap TAP2, a third tap TAP3, a fourth tap TAP4, and an overflow transistor OX. The taps TAP1, TAP2, TAP3, and TAP4 may be adjacent to and/or surround the photoelectric conversion element PD. The taps TAP1, TAP2, TAP3, and TAP4 may be connected to one photoelectric conversion element PD. The taps TAP1, TAP2, TAP3, and TAP4 may share the photoelectric conversion element PD.

The taps TAP1, TAP2, TAP3, and TAP4 may include photo transistors P1, P2, P3, and P4, tap transfer transistors TA1, TA2, TA3, and TA4, storage transistors S1, S2, S3, and S4, transfer transistors TB1, TB2, TB3, and TB4, reset transistors RG1, RG2, RG3, and RG4, source follower transistors SF1, SF2, SF3, and SF4, and selection transistor SEL1, SEL2, SEL3, and SEL4.

The first tap TAP1 may include a first photo transistor P1, a first tap transfer transistor TA1, a first storage transistor S1, a first transfer transistor TB1, a first reset transistor RG1, a first source follower transistor SF1, and a first selection transistor SEL1.

The second tap TAP1 may include a second photo transistor P1, a second tap transfer transistor TA1, a second storage transistor S1, a second transfer transistor TB1, a second reset transistor RG1, a second source follower transistor SF1, and a second selection transistor SEL1.

The third tap TAP1 may include a third photo transistor P1, a third tap transfer transistor TA1, a third storage transistor S1, a third transfer transistor TB1, a third reset transistor RG1, a third source follower transistor SF1, and a third selection transistor SEL1.

The fourth tap TAP1 may include a fourth photo transistor P1, a fourth tap transfer transistor TA1, a fourth storage transistor S1, a fourth transfer transistor TB1, a fourth reset transistor RG1, a fourth source follower transistor SF1, and a fourth selection transistor SEL1.

The photoelectric conversion element PD may generate and accumulate charge based on the light signal RL. For example, the photoelectric conversion element PD may include at least one of a photodiode, a phototransistor, a photogate, or a pinned diode, etc.

The photoelectric conversion element PD may be connected to and disposed between one end of each of the first to fourth photo transistors P1, P2, P3, and P4 and a power voltage GND.

The first to fourth photo transistors P1, P2, P3 and P4 may receive the charge generated by the photoelectric conversion element PD based on first to fourth photo gate signals PS1, PS2, PS3, and PS4, and accumulates the received charge. The charge of the photoelectric conversion element PD may be generated based on the light signal RL. The first to fourth photo gate signals PS1, PS2, PS3, and PS4 may be activated (or enabled) during an exposure (or accumulation) period (or interval) during which the light signal EL is emitted and the light signal RL is incident to the pixel PX, and may be deactivated (or disabled) for a period other than the exposure period.

An amount of charge stored in each of the first to fourth photo transistors P1, P2, P3, and P4 may be determined based on a difference between a phase of each of first to fourth photo gate signals PS1, PS2, PS3, and PS4 and a phase of the light signal EL.

The first to fourth tap transfer transistors TA1, TA2, TA3, and TA4 may be disposed between and connected to the first to fourth storage transistors S1, S2, S3, and S4, respectively, and the first to fourth photo transistors P1, P2, P3, and P4, respectively. The first to fourth tap transfer transistors TA1, TA2, TA3, and TA4 may transfer charge respectively accumulated by the first to fourth tap transfer transistors TA1, TA2, TA3, and TA4 during the exposure period to the first to fourth storage transistors S1, S2, S3, and S4, respectively, based on each of the first to fourth tap transfer gate signals T1, T2, T3, and T4, respectively. The charge accumulated by each of the first to fourth tap transfer transistors TA1, TA2, TA3, and TA4 during a period other than the exposure period may be prevented from being transferred to each of the first to fourth storage transistors S1, S2, S3, and S4.

The first to fourth storage transistors S1, S2, S3, and S4 may be disposed between and connected to each the first to fourth tap transfer transistors TA1, TA2, TA3, and TA4, respectively, and the first to fourth transfer transistors TB1, TB2, TB3, and TB4, respectively. The first to fourth storage transistors S1, S2, S3, and S4 may store the charge accumulated by the first to fourth photo transistors P1, P2, P3, and P4, respectively, based on first to fourth storage gate signals SS1, SS2, SS3, and SS4, respectively. For example, the charge accumulated by the first to fourth photo transistors P1, P2, P3, and P4 may not immediately transferred to a first floating diffusion area FD1, a second floating diffusion area FD2, a third floating diffusion area FD3, and a fourth floating diffusion area FD4, respectively.

The first to fourth transfer transistors TB1, TB2, TB3, and TB4 may be disposed between and connected to the first to fourth storage transistors S1, S2, S3, and S4, respectively, and the first to fourth floating diffusion areas FD1, FD2, FD3, and FD4, respectively. The first to fourth transfer transistors TB1, TB2, TB3, and TB4 may transfer the charge stored in the first to fourth storage transistors S1, S2, S3, and S4, respectively, to the first to fourth floating diffusion areas FD1, FD2, FD3, and FD4, respectively, based on first to fourth transfer gate signals TS1, TS2, TS3, and TS4, respectively.

The first to fourth reset transistors RG1, RG2, RG3, and RG4 may be respectively connected to and disposed between the first to fourth floating diffusion areas FD1, FD2, FD3, and FD4 and a pixel power supply voltage Vpix. The first to fourth reset transistors RG1, RG2, RG3, and RG4 respectively may connect the first to fourth floating diffusion areas FD1, FD2, FD3, and FD4 to the pixel power supply voltage Vpix, based on a first reset gate signal RS1, a second reset gate signal RS2, a third reset gate signal RS3, and a fourth reset gate signal RS4, respectively, such that the charge stored in the first to fourth floating diffusion areas FD1, FD2, FD3, and FD4, respectively, can be removed or discharged, and the first to fourth floating diffusion areas FD1, FD2, FD3, and FD4 can be reset.

A gate of the first to fourth source follower transistors SF1, SF2, SF3, and SF4 may be connected to the first to fourth floating diffusion areas FD1, FD2, FD3, and FD4, respectively. The first to fourth source follower transistors SF1, SF2, SF3, and SF4 respectively may output first to fourth output signals Vout1, Vout2, Vout3, and Vout4, based on a voltage level of each of the first to fourth floating diffusion areas FD1, FD2, FD3, and FD4, respectively.

The first to fourth selection transistor SEL1, SEL2, SEL3, and SEL4 may be connected to and disposed between the first to fourth source follower transistors SF1, SF2, SF3, and SF4, respectively, and an output line. The first to fourth selection transistor SEL1, SEL2, SEL3, and SEL4 may output the first to fourth output signals Vout1, Vout2, Vout3, and Vout4, respectively, based on first to fourth select signals SE1, SE2, SE3, and SE4, respectively. For example, differences between the voltage levels of the first to fourth output signals Vout1, Vout2, Vout3, and Vout4 may represent a distance between the object 40 and the sensing system 100.

An overflow transistor OX may be connected to and disposed between the pixel power supply voltage Vpix and the photoelectric conversion element PD. Due to external light during a time period other than the exposure period, the photoelectric conversion element PD or the first to fourth photo transistors P1, P2, P3, and P4 may accumulate charge. The overflow transistor OX may remove the charge accumulated by the photoelectric conversion element PD and each of the first to fourth photo transistors P1, P2, P3, and P4 during the time period other than the exposure period, or discharge the accumulated charge to the pixel power supply voltage Vpix, based on the overflow gate signal OF. In one or more embodiments, each of the first to fourth taps TAP1, TAP2, TAP3, and TAP4 may include the overflow transistor OX. In one or more embodiments, the first to fourth taps TAP1, TAP2, TAP3, and TAP4 may share the overflow transistor OX.

In one or more embodiments, each of the transistors P1, P2, P3, P4, TA1, TA2, TA3, TA4, S1, S2, S3, S4, TB1, TB2, TB3, TB4, R1, R2, R3, R4, SF1, SF2, SF3, SF4, SEL1, SEL2, SEL3, AND SEL4, and OX in the pixel PX may be embodied as a NMOS transistor.

In one or more embodiments, each of the transistors P1, P2, P3, P4, TA1, TA2, TA3, TA4, S1, S2, S3, S4, TB1, TB2, TB3, TB4, R1, R2, R3, R4, SF1, SF2, SF3, SF4, SEL1, SEL2, SEL3, AND SEL4, and OX in the pixel PX may be embodied as a PMOS transistor.

In one or more embodiments, each of the transistors P1, P2, P3, P4, TA1, TA2, TA3, TA4, S1, S2, S3, S4, TB1, TB2, TB3, TB4, R1, R2, R3, R4, SF1, SF2, SF3, SF4, SEL1, SEL2, SEL3, AND SEL4, and OX in the pixel PX may be embodied as a combination of an NMOS transistor and a PMOS transistor.

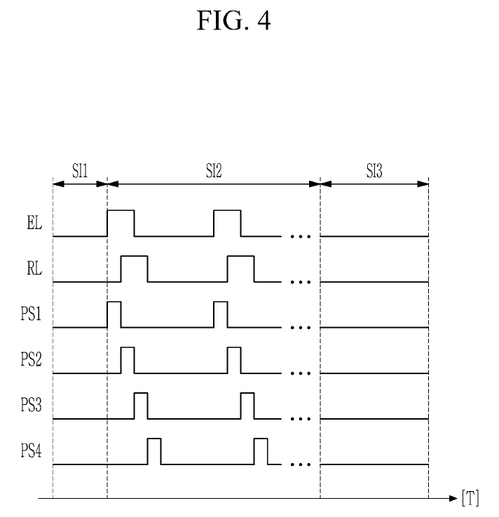

Referring to FIG. 4 with FIG. 1 to FIG. 3, an operation of the depth sensor 20 according to one or more embodiments will be described. FIG. 4 is a timing diagram for explaining an operation of a depth sensor according to one or more embodiments.

Referring to FIG. 4 with FIG. 1 to FIG. 3, a period for reading one frame may include a first period SI1, a second period SI2, and a third period SI3.

The first period SI1 may be a global reset period, the second period SI2 may be an integration period, and the third period SI3 may be a read-out period. The first period SI1, the second period SI2, and the third period SI3 may be repeated.

In the first period SI1 of the global reset period SI1, the pixel PX may be reset. In first period SI1 of the global reset period SI1, the first to fourth floating diffusion areas FD1, FD2, FD3, and FD4 may be reset. No light signal EL may be emitted, and no light signal RL may be incident to the pixel PX.

In the second period SI2 of the integration period, the light signal EL may be emitted to the object 40, and the light signal RL may be incident to the pixel PX. Each of the first to fourth photo transistors P1, P2, P3, and P4 may accumulate the charges, based on each of the first to fourth photo gate signals PS1, PS2, PS3, and PS4. The charges accumulated by the first to fourth photo transistors P1, P2, P3, and P4 may flow through the first to fourth tap transfer transistors TA1, TA2, TA3, and TA4 and then may be stored in the first to fourth storage transistors S1, S2, S3, and S4.

The first to fourth photo gate signals PS1, PS2, PS3, and PS4 may have different phases. The first to fourth photo gate signals PS1, PS2, PS3, and PS4 may have high levels at different times. The first to fourth photo gate signals PS1, PS2, PS3, and PS4 may not temporally overlap each other. For example, the first photo gate signal PS1 may have the same phase as the light signal EL, and the second photo gate signal PS2 may have a phase that differs by 90 degrees from that of the light signal EL. The third photo gate signal PS3 may have a phase that differs by 180 degrees from that of the light signal EL, and the fourth gate photo signal PS4 may have a phase that differs by 270 degrees from that of the light signal EL

The pixels PX may be arranged in rows. In the third period SI3 of the read-out period, a read-out operation may be performed on a row of pixels. No light signal EL may be emitted to the object 40 and the light source 12 may be inactive. In the third period SI3 of the read-out period, the charges stored in the first to fourth storage transistors S1, S2, S3, and S4 may be transferred to the first to fourth floating diffusion areas FD1, FD2, FD3, and FD4, respectively, and may be output based on the first to fourth select signals SE1, SE2, SE3, and SE4, respectively.

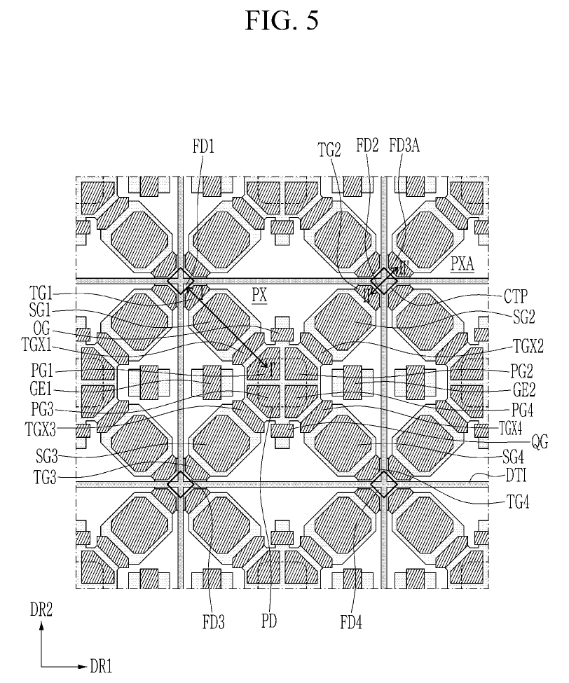

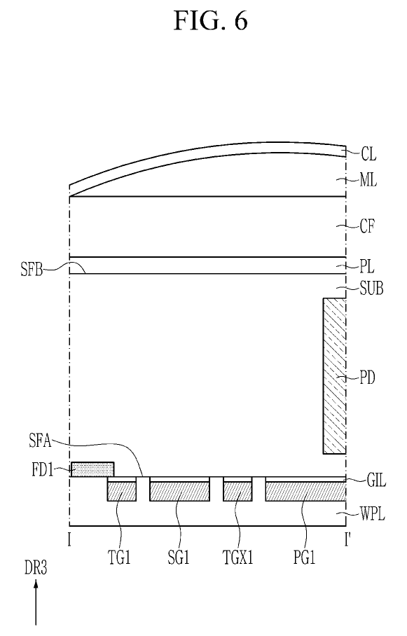

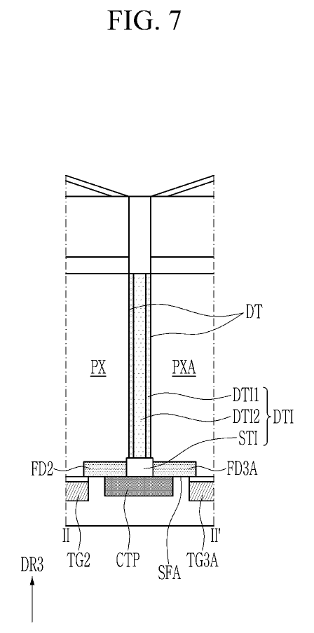

With reference to FIGS. 1 to 3 with FIGS. 5 to 7, a structure of a pixel PX of a depth sensor 20 according to one or more embodiments will be described. FIG. 5 is a plan view showing a portion of a pixel array of a depth sensor according to one or more embodiments, FIG. 6 is a sectional view taken along line I-I' of FIG. 5, and FIG. 7 is a sectional view taken along II-II' of FIG. 5.

Referring to FIG. 5, the depth sensor 20 according to one or more embodiments may include a substrate SUB. The substrate SUB may include a plurality of taps TAP1, TAP2, TAP3, TAP4 corresponding to one pixel PX.

The first tab TAP1 and the second tab TAP2 may be symmetrical to each other along the first direction DR1, and the third tab TAP3 and the fourth tab TAP4 may be symmetrical to the first tab TAP1 and the second tab TAP2 along the second direction DR2, but one or more embodiments is not limited thereto.

The substrate SUB may include, for example, silicon (Si), germanium (Ge), or silicon (Si)-germanium (Ge). The substrate SUB may include may include gallium arsenide (GaAs), indium phosphorus (InP), gallium phosphorus (GaP), indium arsenide (InAs), indium antimony (InSb), or indium gallium arsenide (InGaAs). The substrate SUB may include zinc telluride (ZnTe), or sulfide cadmium (CdS).

The substrate SUB may be, for example, a bulk silicon or a silicon-on-insulator (SOI). The substrate SUB may be a silicon substrate, or may include other materials, for example, silicon germanium, indium antimony, lead tellurium compound, indium arsenide, indium phosphide, gallium arsenide or gallium antimony. As another example, the substrate SUB may be an epitaxial layer formed on a base substrate.

The substrate 200 may be doped with an impurity of a first conductivity type. For example, the first conductivity type may be a P-type.

The substrate SUB may include a first surface SFA and a second surface SFB which are opposed to each other.

A photoelectric conversion element (PD) isolation pattern DTI may at least partially surround an edge of an area where a photoelectric conversion element of the substrate SUB is positioned.

The PD isolation pattern DTI may be located within a deep trench DT of the substrate SUB.

The PD isolation pattern DTI may penetrate the substrate SUB from the first side SFA to the second side SFB of the substrate SUB.

The PD isolation pattern DTI may include a first pattern DTI1, a second pattern DTI2, and a shallow trench isolation pattern STI. The first pattern DTI1 may be provided on and/or cover the inner wall of the deep trench. The second pattern DTI2 may fill the bottom of the deep trench. The shallow trench isolation pattern STI may be located over the first pattern DTI1 and the second pattern DTI2. In one or more embodiments, the shallow trench isolation pattern STI may be connected with the first pattern DTI1 such that they are indistinguishable from each other.

The second pattern DTI2 may be separated from the substrate SUB by the first pattern DTI1 and the shallow trench isolation pattern STI.

The first pattern DTI1 and the shallow trench isolation pattern STI may include, for example, silicon oxide, silicon nitride, or silicon oxynitride. The first pattern DTI1 may include, for example, a metal oxide such as hafnium oxide, aluminum oxide, tantalum oxide, etc., and in this case, the first pattern DTI1 may act as a negative fixed charge layer. The second pattern DTI2 may include a semiconductor material, such as polysilicon doped as n-type or p-type, for example.

The substrate SUB may include pixel areas corresponding to each pixel PX. A photoelectric conversion area PD corresponding to each pixel areas may be located within the substrate SUB. The plurality of tap regions TAPA1, TAPA2, TAPA3, TAPA4 may share one photoelectric conversion element PD.

Light incident from the outside may be converted into electrical signals in the photoelectric conversion element PD. The photoelectric conversion element PD may include a photodiode formed within the substrate SUB. The photoelectric conversion element PD may be doped with a conductive impurity different from the conductive impurity doped in the substrate SUB.

The photoelectric conversion element PD may be doped with a second conductive type impurity different from the first conductive type impurity doped in the substrate SUB. For example, the substrate SUB may be doped with P-type impurities, and the photoelectric conversion element PD may be doped with N-type impurities.

The N-type impurity region of the photoelectric conversion element PD may form a PN junction with the P-type impurity region of the surrounding substrate SUB to form a photodiode, and when light is incident, an electron-hole pair may be generated by the PN junction.

The PD isolation pattern DTI is positioned at least part between regions where photoelectric conversion elements PD of the substrate SUB are positioned, and may electrically and optically isolate photoelectric conversion elements PD of adjacent pixels.

The shallow trench isolation pattern STI located within a shallow trench of the substrate SUB may be located on a portion of the substrate SUB without penetrating the substrate SUB from the first side SFA of the substrate SUB. The depth of the shallow trench isolation pattern STI may be smaller than the depth of the PD isolation pattern DTI along the third direction DR3 which is the height direction.

The shallow trench isolation pattern STI may include, for example, silicon oxide, silicon nitride, or a combination thereof. In one or more embodiments, the shallow trench isolation pattern STI may be an area in which the impurity of the same first conductivity type as the impurity doped in the substrate SUB is doped with a higher concentration than the doping concentration of the impurity doped in the substrate SUB.

In one or more embodiments, the first pattern DTI1 of the PD isolation pattern DTI may be connected to the shallow trench isolation pattern STI, and the shallow trench isolation pattern STI and the first pattern DTI1 may not be distinguished from each other.

A plurality of gate electrodes PG1, PG2, PG3, PG4, TGX1, TGX2, TGX3, TGX4, SG1, SG2, SG3, SG4, TG1, TG2, TG3, TG4, OG may be positioned on the first side SFA of the substrate SUB.

The first tab TAP1 may include a first photo gate electrode PG1 of the first photo transistor P1, a first tab transfer gate electrode TGX1 of the first tab transfer transistor TA1, a first storage gate electrode SG1 of the first storage transistor S1, a first transfer gate electrode TG1 of the first transfer transistor TB1, and the first floating diffusion region FD1.

The second tap TAP2 may include a second photo gate electrode PG2 of the second photo transistor P2, a second tap transfer gate electrode TGX2 of the second tap transfer transistor TA2, a second storage gate electrode SG2 of the second storage transistor S2, a second transfer gate electrode TG2 of the second transfer transistor TB2, and the second floating diffusion region FD2.

The third tap TAP3 may include a third photo gate electrode PG3 of the third photo transistor P3, a third tap transfer gate electrode TGX3 of the third tap transfer transistor TA3, a third storage gate electrode SG3 of the third storage transistor S3, a third transfer gate electrode TG3 of the third transfer transistor TB3, and the third floating diffusion region FD3.

The fourth tap TAP4 may include a fourth photo gate electrode PG4 of the fourth photo transistor P4, a fourth tap transfer gate electrode TGX4 of the fourth tap transfer transistor TA4, a fourth storage gate electrode SG4 of the fourth storage transistor S4, a fourth transfer gate electrode TG4 of the fourth transfer transistor TB4, and the fourth floating diffusion region FD4.

The overflow transistor OX may include an overflow gate electrode OG.

In a top plan view of the first side SFA of the substrate SUB, the pixel PX may have a substantially rectangular planar shape, and the photoelectric conversion element PD may be positioned in the central area of the pixel PX. However, embodiments are not limited thereto.

The photo gate electrodes PG1, PG2, PG3, PG4 may be positioned adjacent to and/or around the photoelectric conversion element PD, and the photo gate electrodes PG1, PG2, PG3, PG4 may overlap the photoelectric conversion element PD along the third direction DR3 in the height direction.

The first photo gate electrode PG1, the first tab transfer gate electrode TGX1, the first storage gate electrode SG1, the first transfer gate electrode TG1 and the first floating diffusion region FD1 of the first tab TAP1 may be sequentially positioned from the center region of the pixel PX to a first vertex of the pixel PX.

The second photo gate electrode PG2, the second tab transfer gate electrode TGX2, the second storage gate electrode SG2, the second transfer gate electrode TG2 and the second floating diffusion region FD2 of the second tab TAP2 may be sequentially positioned from the center region of the pixel PX to a second vertex of the pixel PX.

The third photo gate electrode PG3, the third tab transfer gate electrode TGX3, the third storage gate electrode SG3, the third transfer gate electrode TG3 and the third floating diffusion region FD3 of the third tab TAP3 may be sequentially positioned from the center region of the pixel PX to a third vertex of the pixel PX.

The fourth photo gate electrode PG4, the fourth tab transfer gate electrode TGX4, the fourth storage gate electrode SG4, the fourth transfer gate electrode TG4 and the fourth floating diffusion region FD4 of the fourth tab TAP4 may be sequentially positioned from the center region of the pixel PX to a fourth vertex of the pixel PX.

The pixel PX may include an active region AR positioned adjacent to a first side SFA of the substrate SUB within the substrate SUB, and the active region AR may be separated and spaced apart by the shallow trench isolation pattern STI.

The active area AR of the pixel PX may be an active area for the operation of the plurality of transistors.

The floating diffusion regions FD1, FD2, FD3, FD4 may be positioned adjacent to the first side SFA of the substrate SUB. The floating diffusion regions FD1, FD2, FD3, FD4 may be doped with a second conductivity type impurity different from the first conductivity type impurity doped in the substrate SUB.

A gate insulating layer GIL may be positioned between the first side SFA of the substrate SUB and the plurality of gate electrodes PG1, PG2, PG3, PG4, TGX1, TGX2, TGX3, TGX4, SG1, SG2, SG3, SG4, TG1, TG2, TG3, TG4, OG. The gate insulating layer GIL may include an insulating material such as, for example, silicon oxide, silicon nitride, silicon oxynitride, or a low-k material. The low dielectric material may include at least one of, for example, Flowable Oxide (FOX), Torene SilaZene), Undoped Silica Glass (USG), Borosilica Glass (BSG), PhosphoSilica Glass (PSG), BoroPhosphoSilica Glass (BPSG), Plasma Enhanced Tetra Ethyl Ortho Silicate (PETEOS), Fluoride Silicate Glass (FSG), Carbon Doped Silicon Oxide (CDO), Xerogel, Aerogel, Amorphous Fluorinated Carbon, Organo Silicate Glass (OSG), Parylene, bis-benzocyclobutenes (BCB), SiLK, polyimide, porous polymeric material, and combinations thereof.

A wiring structure WPL may be positioned on the first side SFA of the substrate SUB. The wiring structure WPL may include a plurality of wirings, a plurality of contact plugs, and a plurality of interlayer insulating films forming circuits connected to the transistors P1, P2, P3, P4, TA1, TA2, TA3, TA4, S1, S2, S3, S4, TB1, TB2, TB3, TB4, R1, R2, R3, R4, SF1, SF2, SF3, SF4, SEL1, SEL2, SEL3, AND SEL4, OX.

An anti-reflection layer PL may be positioned on the second side SFB of the substrate SUB. An anti-reflection layer PL may cover the second side SFB of the substrate SUB and the PD isolation pattern DTI.

The antireflection layer PL may include, for example, hafnium oxide (HfO2), silicon oxide (SiO2), silicon nitride (SiN), aluminum oxide (Al2O3), zirconium oxide (ZrO2), tantalum oxide (Ta2O5), titanium oxide (TiO2), lanthanum oxide (La2O3), praseodymium oxide (Pr2O3), cerium oxide (CeO2), neodymium oxide (Nd2O3), promethium oxide (Pm2O3), samarium oxide (Sm2O3), europium oxide (Eu2O3), gadolinium oxide (Gd2O3), terbium oxide (Tb2O3), dysprosium oxide (Dy2O3), holmium oxide (Ho2O3), thulium oxide (Tm2O3), ytterbium oxide (Yb2O3), lutetium oxide (Lu2O3), yttrium oxide (Y2O3), or a combination thereof.

In one or more embodiments, the anti-reflection layer PL may include a plurality of layers comprising different materials and having different thicknesses. For example, the anti-reflection layer PL may include a first anti-reflection layer, a second anti-reflection layer, and a third anti-reflection layer sequentially stacked on the second surface SFB of the substrate SUB

The first anti-reflection layer may be a fixed charge layer with a negative fixed charge. A hole accumulation may occur around the fixed charge layer, thereby more effectively reducing an occurrence of a dark current and white spots.

The third anti-reflection layer is a metal oxide including at least one of, for example, hafnium (Hf), zirconium (Zr), aluminum (Al), tantalum (Ta), titanium (Ti), and yttrium (Y) or a metal fluoride. For example, the first anti-reflection layer and the third anti-reflection layer may include a hafnium oxide layer, and the second anti-reflection layer may include silicon oxide and/or silicon nitride. However, embodiments are not limited thereto, and the number and relative thickness of the layers constituting the anti-reflection layer PL may be varied.

In one or more embodiments, the anti-reflection layer PL may further include a silicon nitride layer disposed between the second anti-reflection layer and the third anti-reflection layer.

Fence patterns IS may be adjacent to and/or surround color filters CF.

The fence patterns IS may include a low refractive index material having a relatively low refractive index. The low refractive index material may have a refractive index greater than approximately 1.0 and less than or equal to approximately 1.4. For example, the low refractive index material may include poly(methyl methacrylate) (PMMA), silicon acrylate (silicon acrylate), cellulose acetate butyrate (CAB), silica (silica), or fluoro-silicon acrylate (FSA). For example, the low refractive index material may include a polymer material with distributed silica (SiOx) particles.

When the fence patterns IS include a low-refractive index material having a relatively low refractive index, light incident on the fence patterns IS may be totally reflected and directed toward the center of each pixel area.

Fence patterns IS may prevent light incident obliquely into the color filter CF arranged in the pixel PX from entering the color filter CF arranged in another adjacent pixel, thereby preventing crosstalk between adjacent pixels.

The plurality of color filters CF may be positioned on anti-reflection layer PL and separated from each other by the fence pattern IS. The plurality of color filters CF may include, for example, a green filter, a blue filter, and a red filter. The plurality of color filters CF may include, for example, cyan, magenta, or yellow.

A micro lens ML may be positioned on the color filter CF and the fence pattern IS.

The micro lens ML may be transparent. The micro lens ML may be formed of a resin-based material such as, for example, styrene-based resin, acryl-based resin, styrene-acryl copolymerization-based resin, or siloxane-based resin.

The micro lens ML may collect the incident light, and the collected light may be incident on the photoelectric conversion area PD through the color filter CF.

A capping layer CL may be positioned on the micro lens ML to protect the micro lens ML.

Each of the floating diffusion regions FD1, FD2, FD3, FD4 of each pixel PX may be connected to the floating diffusion regions of adjacent pixels PXA through a connecting portion CTP located on the first side SFA of the substrate SUB.

As described above, the first floating diffusion area FD1 of the first tap TAP1 may be positioned adjacent to the first vertex and may be connected to the floating diffusion areas of three adjacent pixels adjacent to the first vertex through the connecting portion CTP. The second floating diffusion region FD2 of the second tap TAP2 may be positioned adjacent to the second vertex and connected to the floating diffusion regions of three adjacent pixels adjacent to the second vertex through a connecting portion CTP. The third floating diffusion area FD3 of the third tap TAP3 may be positioned adjacent to the third vertex and connected to the floating diffusion areas of three adjacent pixels adjacent to the third vertex through a connecting portion CTP. The fourth floating diffusion area FD4 of the fourth tap TAP4 may be positioned adjacent to the fourth vertex and connected to the floating diffusion areas of three adjacent pixels adjacent to the fourth vertex through a connecting portion CTP.

Referring to FIG. 7, the connection portion CTP may be positioned on the first side SFA of the substrate SUB, and the connection portion CTP may be in contact with the floating diffusion area FD2 of the pixel PX and the floating diffusion area FD3A of the adjacent pixel PXA. At least a portion of the floating diffusion region FD3A of the adjacent pixel PXA may overlap the photo gate electrode PG3A of the adjacent pixel PXA along the height direction DR3.

The PD isolation pattern DTI may be positioned on the substrate SUB between the pixel PX and the pixel PXA.

A portion of the connection CTP may be positioned over the PD isolation pattern DTI.

The connecting portion CTP may include at least one of, for example, doped polysilicon (poly Si), a metal silicide such as cobalt silicide, a metal nitride such as titanium nitride, and a metal such as tungsten, copper, and aluminum. However, one or more embodiments is not limited thereto. For example, the connection CTP may include a same layer with at least one of the gate electrodes PG1, PG2, PG3, PG4, TGX1, TGX2, TGX3, TGX4, SG1, SG2, SG3, SG4, TG1, TG2, TG3, TG4, OG. In this disclosure, including the same layer may indicate including the same material and being formed together through the same process.

According to one or more embodiments, the floating diffusion areas of the pixel PX and the adjacent pixel PXA are connected to each other, and thereby the area of the floating diffusion areas may be maintained wide even when the size of the pixels PX and PXA is reduced. Accordingly, the sensor's operating characteristics may be maintained even as the pixel PX size decreases.

The connectors CTP may be located at the four corners of a pixel PX and may overlap adjacent pixels PXA.

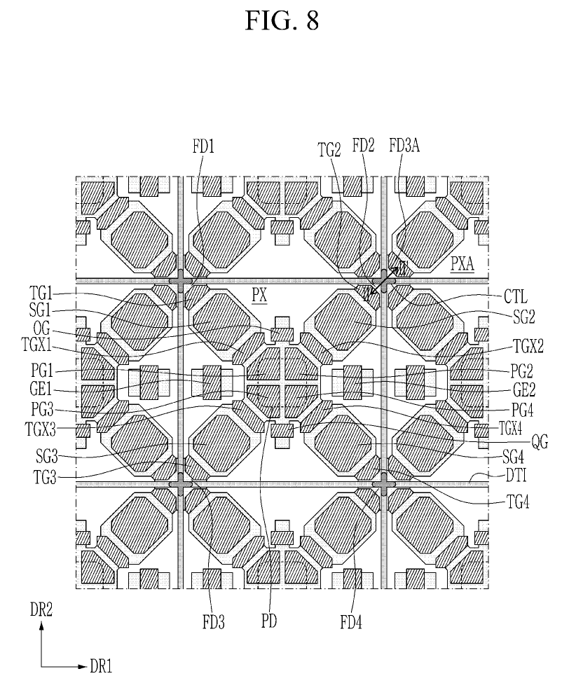

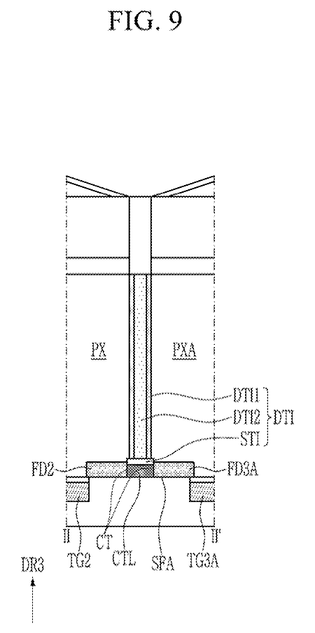

With reference to FIGS. 1 to 3 with FIGS. 8 and 9, the structure of a pixel PX of the depth sensor 20 according to one or more other embodiments will be described. FIG. 8 is a plan view showing a portion of a pixel array of a depth sensor according to one or more other embodiments and FIG. 9 is a cross-sectional view taken along line II-II' of FIG. 8.

Referring to FIG. 8, the structure of the pixel PX of the depth sensor 20 according to one or more embodiments is similar to the structure of the pixel PX of the depth sensor 20 according to one or more embodiments described above. Detailed descriptions of the same components are omitted.

Referring to FIGS. 8 and 9, a pixel PX may include a connection layer CTL adjacent to a first side SFA of a substrate SUB.

Each of the floating diffusion regions FD1, FD2, FD3, FD4 of each pixel PX may be connected to the floating diffusion regions of adjacent pixels PXA through the connection layer CTL positioned adjacent to the first side SFA of the substrate SUB.

As described above, the first floating diffusion region FD1 of the first tap TAP1 may be positioned adjacent to the first vertex and may be connected to the floating diffusion regions of three adjacent pixels adjacent to the first vertex through the connection layer CTL. The second floating diffusion region FD2 of the second tap TAP2 may be positioned adjacent to the second vertex and connected to the floating diffusion regions of three adjacent pixels adjacent to the second vertex through the connection layer CTL. The third floating diffusion region FD3 of the third tap TAP3 may be positioned adjacent to the third vertex and connected to the floating diffusion regions of three adjacent pixels adjacent to the third vertex through the connection layer CTL. The fourth floating diffusion region FD4 of the fourth tap TAP4 may be positioned adjacent to the fourth vertex and may be connected to the floating diffusion regions of three adjacent pixels adjacent to the fourth vertex through the connection layer CTL.

The connecting layer CTL may overlap with the PD isolation pattern DTI.

The connecting layer CTL may be positioned within a groove CT formed on the first surface SFA of the substrate SUB, and may be positioned on side surfaces of floating diffusion regions of four adjacent pixels so as to contact the side surfaces of the floating diffusion regions of the four adjacent pixels, thereby electrically connecting the floating diffusion regions of the four adjacent pixels.

The connecting layer CTL may be a cross-shaped planar shape having a substantially same width as a width of the PD isolation pattern DTI in the first direction DR1 and/or the second direction DR2.

In FIGS. 8 and 9, the groove CT in which the connection layer CTL is positioned may be aligned with the PD isolation pattern DTI along the third direction DR3 in the height direction, and the connection layer CTL may have a cross-shaped planar shape, but one or more embodiments is not limited thereto. The groove CT in which the connection layer CTL is positioned may be greater than the PD isolation pattern DTI, and the planar shape of the connection layer CTL may also be varied.

The connecting layer CTL may include at least one of, for example, doped polysilicon (poly Si), a metal silicide such as cobalt silicide, a metal nitride such as titanium nitride, and a metal such as tungsten, copper, and aluminum. However, one or more embodiments is not limited thereto. For example, the connecting layer CTL may include a same layer with at least one of the gate electrodes PG1, PG2, PG3, PG4, TGX1, TGX2, TGX3, TGX4, SG1, SG2, SG3, SG4, TG1, TG2, TG3, TG4, OG.

According to one or more embodiments, the floating diffusion areas of the pixel PX and the adjacent pixel PXA are connected to each other, and thereby the area of the floating diffusion area may be maintained wide even if the size of the pixel PX is reduced. Accordingly, the sensor's operating characteristics may be maintained even as the pixel PX size decreases.

The connection layer CTL may be located at the four corners of the pixel PX and may overlap with the adjacent pixel PXA.

Many of the features of the depth sensor according to one or more embodiments described above with reference to FIGS. 1 to 7 are all applicable to the depth sensor according to one or more embodiments.

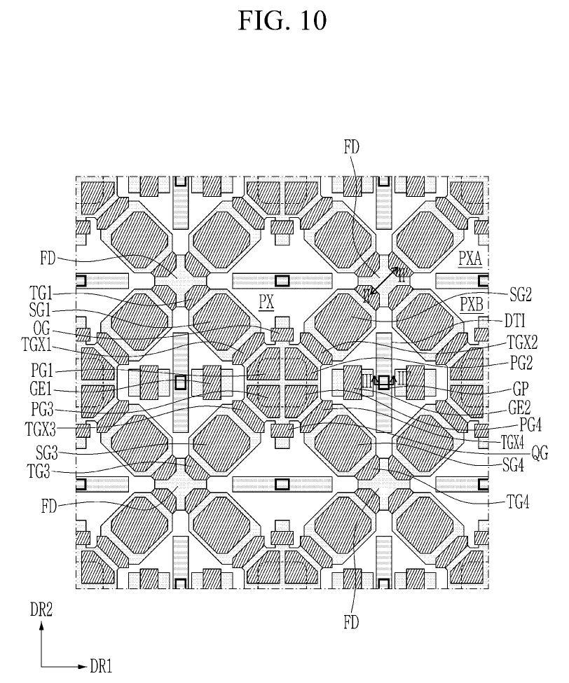

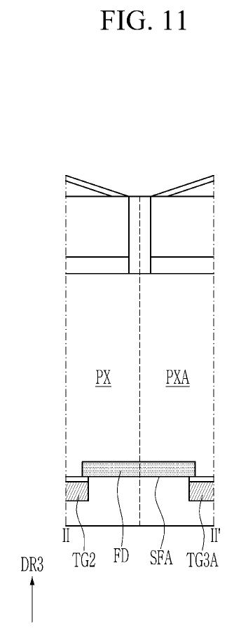

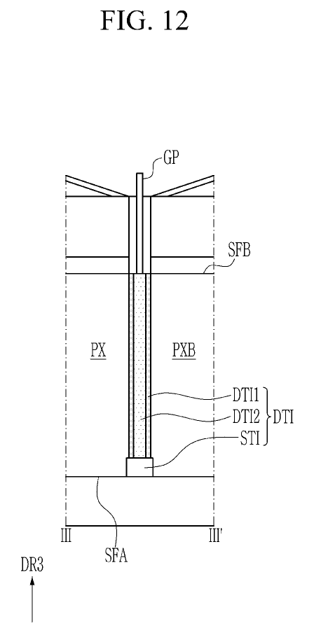

With reference to FIGS. 1 to 3 and FIGS. 10 to 12, the structure of a pixel PX of a depth sensor 20 according to one or more other embodiments will be described. FIG. 10 is a plan view showing a part of a pixel array of a depth sensor according to one or more other embodiments, FIG. 11 is a sectional view taken along line II-II' of FIG. 10, and FIG. 12 is a sectional view taken along the line III-III' of FIG. 10.

Referring to FIGS. 10 and 11, the structure of the pixel PX of the depth sensor 20 according to one or more embodiments is similar to the structure of the pixel PX of the depth sensor 20 according to one or more embodiments described above. Detailed descriptions of the same components are omitted

The pixel PX and the adjacent pixel PXB of the depth sensor 20 according to one or more embodiments may share a floating diffusion region FD.

As described above, floating diffusion regions FD may be located at four corners of the area of the pixel PX, and the floating diffusion regions FD located at each corner may be formed integrally with the floating diffusion regions of three adjacent pixels and shared with each other.

The PD isolation pattern DTI may not be located at positions corresponding to the floating diffusion areas FD.

The PD isolation pattern DTI may be separated from each other and not connected to each other in the floating diffusion regions FD.

Referring to FIG. 12, according to one or more embodiments, a pad portion GP may be positioned on the second side SFB of the substrate SUB.

The pad portion GP may contact the second pattern DTI2 of the PD isolation pattern DTI located between adjacent pixels PX, PXB.

A fixed voltage, such as a ground voltage, may be applied to the PD isolation pattern DTI through the pad portion GP. When fixed voltage is not applied to the PD isolation pattern DTI and the PD isolation pattern DTI is left floating, the transistors and photoelectric conversion element PD of the pixel PX and the PD isolation pattern DTI may be coupled unnecessarily, and noise may be generated in the depth sensor 20 due to this unnecessary coupling.

When the PD isolation pattern DTI surrounds the area where the photoelectric conversion element of the pixel PX is located and is connected to each other in a grid shape, by applying voltage to the PD isolation pattern DTI located at the outermost side, the same voltage may be applied to the entire PD isolation pattern DTI. When the PD isolation patterns DTIs are not connected to each other but spaced apart from each other, the voltage applied to some of the PD isolation pattern is not transmitted to the entire PD isolation pattern.

According to one or more embodiments, a voltage may be applied to each PD isolation pattern DTI separated through the pad portion GP located on the second side SFB of the substrate SUB. Accordingly, the voltage may be more stably applied to each separated PD isolation pattern DTI while adjacent pixels share the floating diffusion region.

The pad portion GP is positioned on the second side SFB facing the first side SFA of the substrate SUB, to not affect the arrangement of the active region AR, gate electrodes PG1, PG2, PG3, PG4, TGX1, TGX2, TGX3, TGX4, SG1, SG2, SG3, SG4, TG1, TG2, TG3, TG4, OG and floating diffusion region FD adjacent to the first side SFA of the substrate SUB.

According to one or more embodiments, pixels adjacent to the pixel PX share the floating diffusion region, so that even when the size of the pixel PX decreases, the area of the floating diffusion region may be maintained to be relatively large. Accordingly, the sensor's operating characteristics may be maintained even as the pixel PX size decreases.

Many of the features of the depth sensors according to one or more embodiments described above with reference to FIGS. 1 to 9 are all applicable to the depth sensor according to the present embodiment.

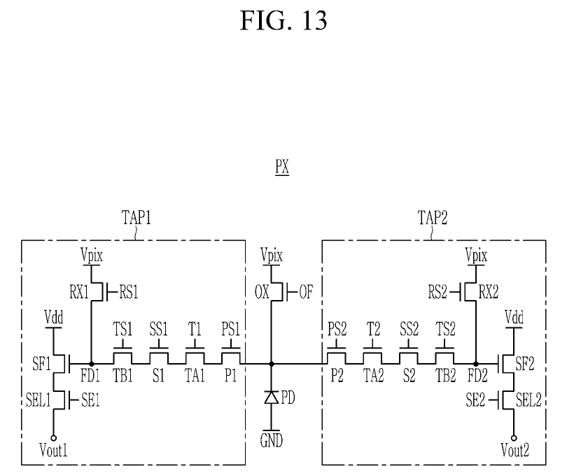

Referring to FIG. 13, a depth sensor according to one or more embodiments will be described. FIG. 13 is an equivalent circuit diagram of a single pixel of a depth sensor according to one or more embodiments.

For convenience of description, the following descriptions are based on differences from the descriptions presented above with reference to FIG. 3 and FIG. 4.

Referring to FIG. 13, the pixel PX may have a 2-tap structure. The pixel PX may include the photoelectric conversion element PD, the first tap TAP1, the second tap TAP2, and the overflow transistor OX. The first tap TAP1 and the second tap TAP2 may be connected to one photoelectric conversion element PD. The first tap TAP1 and the second tap TAP2 may share the photoelectric conversion element PD

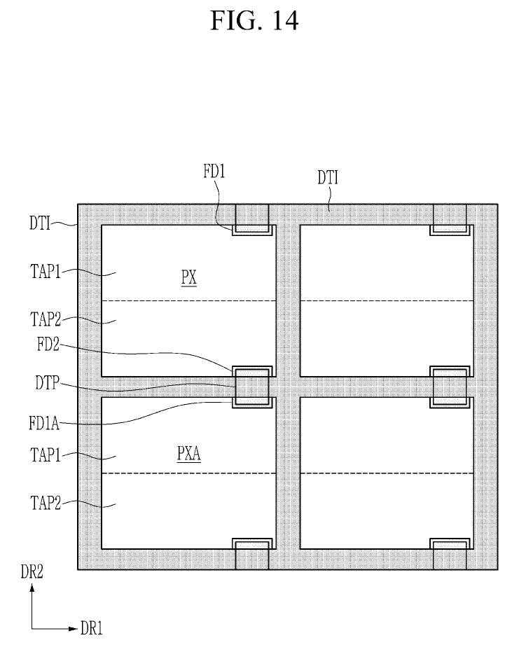

Referring to FIG. 14 with FIG. 13, a pixel structure of a depth sensor according to one or more embodiments is described. FIG. 14 is a plan view showing a part of a pixel array of a depth sensor according to one or more embodiments. For convenience of explanation, only a part of the pixel structure is shown in FIG. 14.

Referring to FIG. 14, the pixel PX may include the first tab TAP1 and the second tab TAP2. The first tab TAP1 and the second tab TAP2 of the pixel PX may be surrounded by the PD isolation pattern DTI.

The first tab TAP1 of the pixel PX may include a first floating diffusion region FD1, and the second tab TAP2 may include a second floating diffusion region FD2.

The first floating diffusion region FD1 of the first tab TAP1 and the second floating diffusion region FD2 of the second tab TAP2 of the pixel PX may be arranged in a row along the second direction DR2.

The second floating diffusion area FD2 of the second tap TAP2 of the pixel PX may be connected to a first floating diffusion area FD1A of a first tap TAP1 of an adjacent pixel PXA adjacent to the pixel PX along a second direction DR2 through a connection pattern DTP.

The connection pattern DTP may be similar to the connection portion CTP or the connection layer CTL described above through FIG. 7 or FIG. 9. Detailed descriptions of the connection pattern DTP are omitted.

According to one or more embodiments, the floating diffusion areas of the pixel PX and the adjacent pixel PXA are connected to each other, the area of the floating diffusion area may be maintained wide even when the size of the pixel PX is reduced. Accordingly, the sensor's operating characteristics may be maintained even as the pixel PX size decreases.

Many of the features of the depth sensors according to one or more embodiments described above are all applicable to the depth sensor according to the present embodiment.

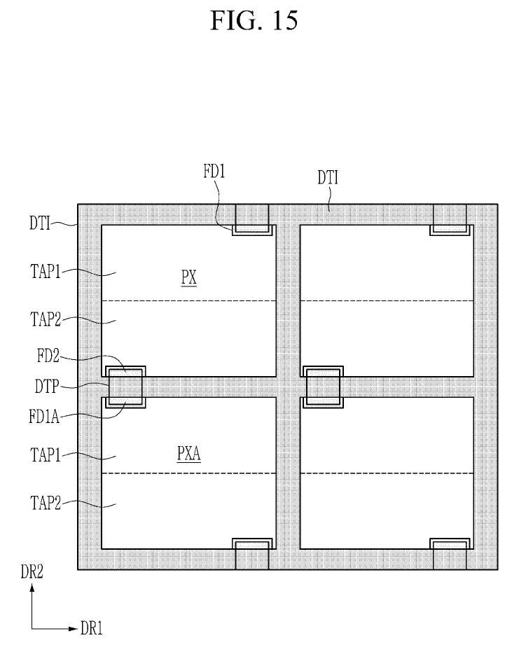

Referring to FIG. 15 together with FIG. 13 and FIG. 14, a pixel structure of a depth sensor according to one or more other embodiments is described. FIG. 15 is a plan view showing a part of a pixel array of a depth sensor according to one or more embodiments. For convenience of explanation, only a part of the pixel structure is shown in FIG. 15.

Referring to FIG. 15, the depth sensor according to one or more embodiments is similar to the depth sensor according to one or more embodiments illustrated in FIG. 14. However, in the depth sensor according to one or more embodiments, unlike the depth sensor according to one or more embodiments illustrated in FIG. 14, the first floating diffusion region FD1 of the first tap TAP1 of the pixel PX and the second floating diffusion region FD2 of the second tap TAP2 may not be aligned along the second direction DR2, but may be positioned in a direction diagonal to each other along the second direction DR2.

The second floating diffusion area FD2 of the second tap TAP2 of the pixel PX may be connected to the first floating diffusion area FD1A of the first tap TAP1 of the adjacent pixel PXA adjacent to the pixel PX along the second direction DR2 through the connection pattern DTP.

The connection patterns DTPs may be arranged in a zigzag manner along the second direction DR2.

The connection pattern DTP may be similar to the connection portion CTP or the connection layer CTL according to one or more embodiments described above through FIG. 7 or FIG. 9. Detailed descriptions of the connection pattern DTP are omitted.

According to one or more embodiments, the floating diffusion areas of the pixel PX and the adjacent pixel PXA are connected to each other, and thereby the area of the floating diffusion area may be maintained to be relatively large even when the size of the pixel PX is reduced. Accordingly, the sensor's operating characteristics may be maintained even as the pixel PX size decreases.

Many of the features of the depth sensors according to the embodiments described above are all applicable to the depth sensor according to one or more embodiments.

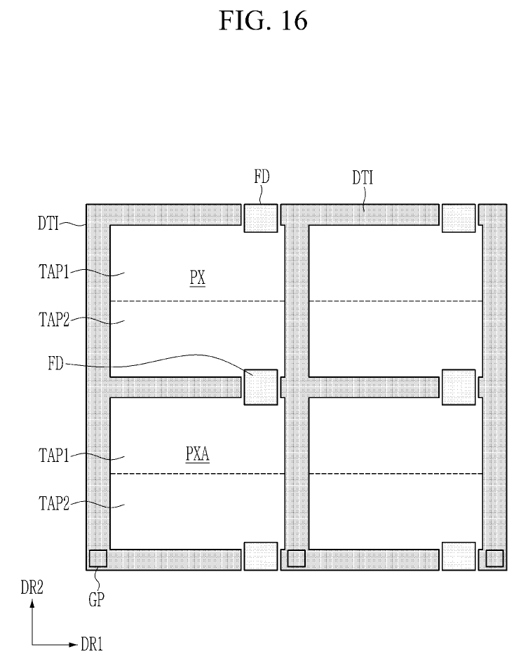

Referring to FIG. 16 with FIGS. 13 to 15, a pixel structure of a depth sensor according to one or more other embodiments will be described. FIG. 16 is a plan view showing a part of a pixel array of a depth sensor according to one or more embodiments. For convenience of explanation, only a part of the pixel structure is shown in FIG. 16.

Referring to FIG. 16, the depth sensor according to one or more embodiments is similar to the depth sensor according to the embodiment illustrated in FIG. 14. However, unlike the depth sensor according to one or more embodiments illustrated in FIG. 14, the depth sensor according to the present embodiment may share a floating diffusion region FD with adjacent pixels PX, PXA along the second direction DR2.

The PD isolation pattern DTI may be separated and spaced from each other at the position corresponding to the floating diffusion region FD, and the separated PD isolation pattern DTI may receive voltage through the pad portion GP.

The pad portion GP may be similar to the pad portion GP according to one or more embodiments described with reference to FIG. 12. Detailed descriptions of the pad portion GP are omitted.

According to one or more embodiments, the pixel PX and the adjacent pixel PXA may share the floating diffusion area, the area of the floating diffusion area may be maintained wide even if the size of the pixel PX is reduced. Accordingly, the sensor's operating characteristics may be maintained even as the pixel PX size decreases.

Additionally, the voltage may be applied to each PD isolation pattern DTI separated through the pad portion GP. Therefore, voltage may be more stably applied to each separated PD isolation pattern DTI while adjacent pixels share a floating diffusion region.

Many of the features of the depth sensors according to the embodiments described above are all applicable to the depth sensor according to one or more embodiments.

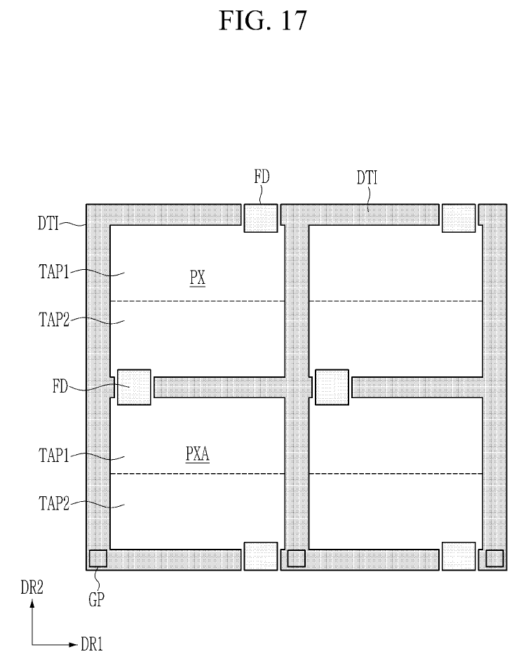

Referring to FIG. 17 with FIGS. 13 to 16, a pixel structure of a depth sensor according to one or more other embodiments will be described. FIG. 17 is a plan view showing a part of a pixel array of a depth sensor according to one or more embodiments. For convenience of explanation, only a part of the pixel structure is shown in FIG. 17.

Referring to FIG. 17, the depth sensor according to the present embodiment is similar to the depth sensor according to one or more embodiments illustrated in FIG. 16. Adjacent pixels PX, PXA along the second direction DR2 may share a floating diffusion region FD.

However, unlike the depth sensor according to one or more embodiments illustrated in FIG. 16, the floating diffusion regions FD according to one or more embodiments are not arranged in a row along the second direction DR2, but may be positioned in a direction diagonal to each other along the second direction DR2. For example, the floating diffusion regions FD may be spaced apart from each other in the first direction DR1.

The floating diffusion regions FD may be arranged in a zigzag manner along the second direction DR2.

The PD isolation pattern DTI may be separated and spaced from each other at the position corresponding to the floating diffusion region FD, and the separated PD isolation pattern DTI may receive the voltage through the pad portion GP.

The pad portion GP may be similar to the pad portion GP according to one or more embodiments described with reference to FIG. 12. Detailed descriptions of the pad portion GP are omitted.

According to one or more embodiments, the pixel PX and the adjacent pixel PXA share the floating diffusion area, the area of the floating diffusion area may be maintained wide even if the size of the pixel PX is reduced. Accordingly, the sensor's operating characteristics may be maintained even as the pixel PX size decreases.

Additionally, a voltage may be applied to each PD isolation pattern DTI separated through the pad portion GP. Accordingly, voltage may be more stably applied to each separated PD isolation pattern DTI while adjacent pixels share a floating diffusion region.

Many of the features of the depth sensors according to the embodiments described above are all applicable to the depth sensor according to one or more embodiments.

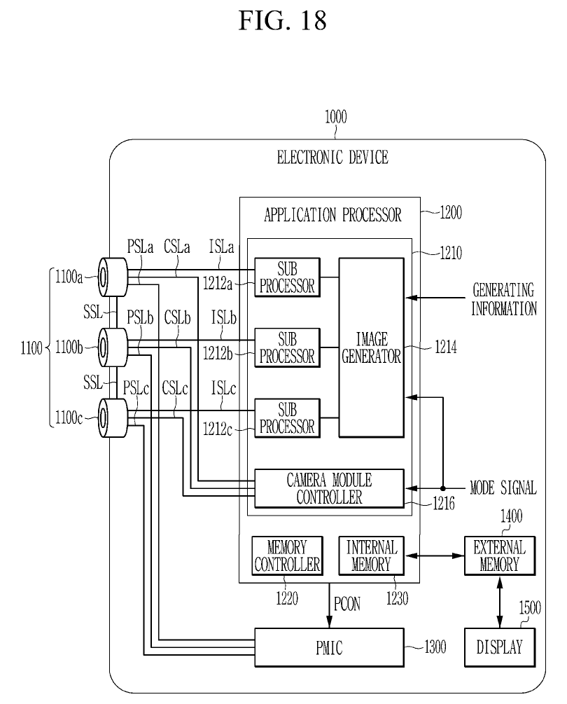

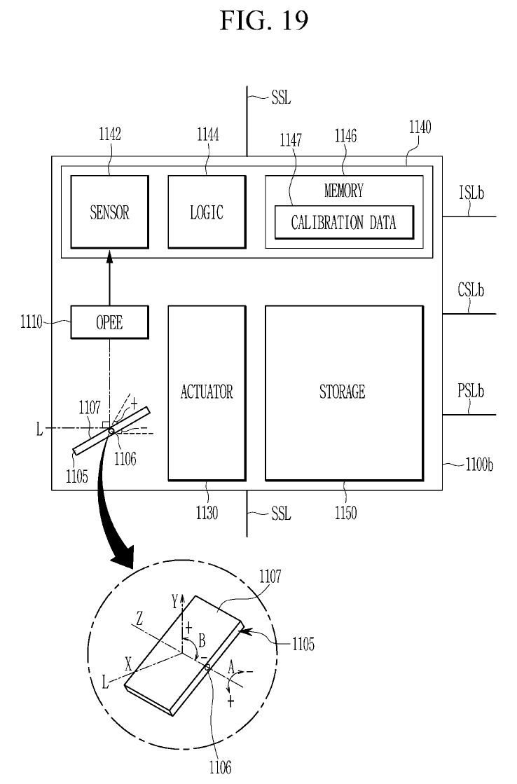

Referring to FIG. 18 and FIG. 19, an electronic device including the depth sensor according to one or more embodiments will be described. FIG. 18 is a block diagram of an electronic device including a depth sensor according to one or more embodiments and FIG. 19 is a detailed block diagram of a camera module of the electronic device in FIG. 18.

Referring to FIG. 18, in one or more embodiments, an electronic device 1000 includes a camera module group 1100, an application processor 1200, a power management integrated circuit (PMIC) 1300, an external memory 1400, and a display monitor 1500.

The camera module group 1100 may include a plurality of camera modules 1100a, 1100b, and 1100c. One of the plurality of camera modules 1100a, 1100b, and 1100c may be a depth sensor as described with reference to FIG. 1 to FIG. 17. Although FIG. 18 shows one or more embodiments in which three camera modules 1100a, 1100b, and 1100c are arranged, embodiments are not necessarily limited thereto

The application processor 1200 may include an image processing device 1210, a memory controller 1220, and an internal memory 1230. The application processor 1200 may be separated from the plurality of camera modules 1100a, 1100b, and 1100c. For example, the application processor 1200 and the plurality of camera modules 1100a, 1100b, and 1100c may be implemented as separate semiconductor chips that are separated from each other.

The image processing device 1210 may include a plurality of auxiliary image processors 1212a, 1212b, and 1212c, an image generator 1214 and a camera module controller 1216.

The number of the auxiliary image processors 1212a, 1212b, and 1212c may correspond to the number of camera modules 1100a, 1100b, and 1100c.

Image data generated from each of the camera modules 1100a, 1100b, and 1100c may be provided to each of the auxiliary image processors 1212a, 1212b, and 1212c by separate image signal lines ISLa, ISLb, and ISLc, respectively. For example, the image data generated from the camera module 1100a may be transmitted to the auxiliary image processor 1212a through the image signal line ISLa. The image data generated from the camera module 1100b may be transmitted to the auxiliary image processor 1212b through the image signal line ISLb. The image data generated from the camera module 1100c may be transmitted to the auxiliary image processor 1212c through the image signal line ISLc. The image data transmission may be performed by using, for example, a camera serial interface (CSI) based on a MIPI (Mobile Industry Processor Interface). However, embodiments of the present disclosure are not necessarily limited thereto.

In some embodiments, one auxiliary image processor may correspond to a plurality of camera modules. For example, the auxiliary image processor 1212a and the auxiliary image processor 1212c may be not implemented separately from each other as shown, but may be integrated into one auxiliary image processor. The image data provided from the camera module 1100a and the camera module 1100c can be selected by a selection element, such as a multiplexer, and then be provided to the integrated auxiliary image processor.

The image data provided to each of the auxiliary image processors 1212a, 1212b, and 1212c may be provided to the image generator 1214. The image generator 1214 may generate an output image using the image data received from each of the auxiliary image processors 1212a, 1212b, and 1212c based on image generation information or a mode signal.

In one or more embodiments, the image generator 1214 may merge at least a portion of the image data received from camera modules 1100a, 1100b, and 1100c that have different FOVs, based on the image generation information or the mode signal, and may generate the output image as the merging result. In one or more embodiments, the image generator 1214 may select one set of image data received from camera modules 1100a, 1100b, and 1100c that have different FOVs, based on the image generation information or the mode signal, and may generate the output image as the selected data.

In one or more embodiments, the image generation information may include a zoom signal or a zoom factor. Further, in one or more embodiments, the mode signal may be, for example, a signal based on a user selected mode.

When the image generation information includes a zoom signal or a zoom factor, and the camera modules 1100a, 1100b, and 1100c have different FOVs, the image generator 1214 may perform different operations based on the zoom signal. For example, when the zoom signal is a first signal, the image generator may merge the image data received from the camera module 1100a and the image data received from the camera module 1100c with each other, and may generate the output image using the merged image data. The image data received from the camera module 1100b may not be used in this merging operation. When the zoom signal is a second signal different from the first signal, the image generator 1214 may not perform an image data merging operation, but may select one set of image data received from the camera modules 1100a, 1100b, and 1100c and may generate the selected data as the output image. However, embodiments are not limited thereto. One or more embodiments for processing the image data can be modified as needed.

In one or more embodiments, the image generator 1214 may receive a plurality of image data that have different exposure times from at least one of the plurality of auxiliary image processors 1212a, 1212b, and 1212c, and may perform high dynamic range (HDR) processing on the received plurality of image data, thereby generating merged image data having an increased dynamic range.

The camera module controller 1216 may provide a control signal to each of the camera modules 1100a, 1100b, and 1100c. The control signal received from the camera module controller 1216 may be provided to a corresponding camera module 1100a, 1100b, or 1100c through a corresponding control signal line CSLa, CSLb, or CSLc that are separated from each other.

In one or more embodiments, one of the plurality of camera modules 1100a, 1100b, or 1100c, such as 1100b, may be designated as a master camera based on the image generation information that includes the zoom signal or the mode signal, while each of the remaining camera modules, such as 1100a and 1100c, may be designated as a servant camera. This designation information may be included in the control signal and may be provided to the corresponding camera module 1100a, 1100b, or 1100c through a corresponding control signal line CSLa, CSLb, or CSLc.

The camera module that acts as the master or servant camera may vary based on the zoom factor or an operation mode signal. For example, when the FOV of the camera module 1100a is greater than that of the camera module 1100b, and the zoom factor indicates a low zoom ratio, the camera module 1100b may act as a master camera, while the camera module 1100a may act as a servant camera.

When the zoom factor indicates a relatively high zoom ratio, the camera module 1100a may act as a master camera, while the camera module 1100b may act as a servant camera.

In one or more embodiments, the control signal from the camera module controller 1216 provided to each of the camera modules 1100a, 1100b, and 1100c may include a sync enable signal. For example, when the camera module 1100b is the master camera, and each of the camera modules 1100a and 1100c may be a servant camera, the camera module controller 1216 may transmit the sync enable signal to the camera module 1100b. Upon receiving a sync enable signal, the camera module 1100b may generate a sync signal based on the provided sync enable signal, and may provide the generated sync signal to the camera modules 1100a and 1100c through a sync signal line SSL. The camera module 1100b and the camera modules 1100a and 1100c may transmit the image data to the application processor 1200 while the camera module 1100b and the camera modules 1100a and 1100c may be synchronized with each other using the sync signal.

In one or more embodiments, the control signal from the camera module controller 1216 provided to each of the plurality of camera modules 1100a, 1100b, and 1100c may include mode information according to the mode signal. Based on this mode information, the plurality of camera modules 1100a, 1100b, and 1100c may operate in a first operation mode or a second operation mode in relation to a sensing speed.

In a first operation mode, the plurality of camera modules 1100a, 1100b, and 1100c may generate an image signal at a first speed, such as a first frame rate, may encode the image signal at a second speed higher than the first speed, such as a second frame rate higher than the first frame rate, and may transmit the encoded image signal to the application processor 1200. For example, the second speed may be less than or equal to 30 times of the first speed.

The application processor 1200 may store the received image signal, that is, the encoded image signal, in the internal memory 1230 or the external memory 1400, and then may read and decode the encoded image signal from the internal memory 1230 or the external memory 1400, and then may display image data generated from the decoded image signal on the display monitor 1500. For example, a corresponding auxiliary processor of the plurality of auxiliary processors 1212a, 1212b, and 1212c of the image processing device 1210 may decode the image signal, and may perform image processing on the decoded image signal.

In a second operation mode, the plurality of camera modules 1100a, 1100b, and 1100c may generate an image signal at a third speed lower than the first speed, such as a third frame rate lower than the first frame rate, and then may transmit the image signal to the application processor 1200. The image signal transmitted to the application processor 1200 may be an unencoded signal. The application processor 1200 may perform image processing on the received image signal or may store the image signal in the internal memory 1230 or the external memory 1400.

The PMIC 1300 may supply power, such as a power supply voltage, to each of the plurality of camera modules 1100a, 1100b, and 1100c. For example, the PMIC 1300 may supply first power to the camera module 1100a through a first power signal line PSLa, may supply second power to the camera module 1100b through a second power signal line PSLb, and may supply third power to the camera module 1100c through a third power signal line PSLc, under control of the application processor 1200.

The PMIC 1300 may generate power that corresponds to each of the plurality of camera modules 1100a, 1100b, and 1100c and may adjust a power level, in response to a power control signal PCON received from the application processor 1200. The power control signal PCON may include an operation mode-based power adjustment signal for the plurality of camera modules 1100a, 1100b, and 1100c. For example, the operation mode may include a low power mode. For example, the power control signal PCON may include information about a camera module that operates in the low power mode and information about a set power level. Power levels respectively provided to the plurality of camera modules 1100a, 1100b, and 1100c may be the same as or different from each other. Further, the power levels may vary dynamically.

Referring to FIG. 19, a detailed configuration of the camera module 1100b will be described. However, the following description may be equally applied to other camera modules 1100a and 1100c, according to one or more embodiments.

Referring to FIG. 19, the camera module 1100b may include a prism 1105, an optical path folding element (OPFE) 1110, an actuator 1130, an image sensing device 1140, and storage 1150.

The prism 1105 may include a reflective face 1107 made of a reflective material, and thus may modify a path of externally incident light L.

In one or more embodiments, the prism 1105 may change the path of the light L such that the light incident thereto in the first direction X may be output therefrom in a second direction Y perpendicular to the first direction X. Further, the prism 1105 may rotate the reflective face 1107 of the reflective material in an A direction about a central axis 1106 or may rotate the central axis 1106 in a B direction so that the light incident thereto in the first direction X may be output therefrom in the second direction Y perpendicular to the first direction X. In this connection, the OPFE 1110 may move in a third direction Z normal to a plane defined by the first direction X and the second direction Y.

In one or more embodiments, as shown, a maximum rotation angle in the A direction of the prism 1105 may be less than or equal to 15 degrees in a plus (+) A direction, and may be greater than 15 degrees in a minus (−) A direction. However, embodiments of the present disclosure are not necessarily limited thereto.

In one or more embodiments, the prism 1105 may rotate in a range of about 20 degrees, or between 10 and 20 degrees, or between 15 and 20 degrees in the plus (+) or minus (−) B direction. In this regard, the prism 1105 may rotate by the same angle in the plus (+) and minus (−) B directions. As another example, in one or more embodiments, angles by which the prism 1105 may rotate in the plus (+) and minus (−) B directions, respectively, have a difference of about 1 degree therebetween.

In one or more embodiments, the prism 1105 may move the reflective face 1107 in the third direction, such as the Z direction parallel to an extension direction of the center axis 1106.

The OPFE 1110 may include a group of m optical lens, where m is a positive integer. The group of m optical lenses may move in the second direction Y to change an optical zoom ratio of the camera module 1100b. For example, when a basic optical zoom ratio of the camera module 1100b is Z, the optical zoom ratio of the camera module 1100b may change to an optical zoom ratio equal to or greater than 3Z or 5Z if the m optical lenses in the OPFE 1110 move.

The actuator 1130 may move the OPFE 1110 or the optical lens to a specific position. For example, the actuator 1130 may adjust a position of the optical lens such that an image sensor 1142 is located at a focal length of the optical lens for accurate sensing

The image sensing device 1140 may include the image sensor 1142, a control logic 1144 and a memory 1146. The image sensor 1142 may sense an image of a sensing target using the light L received through the optical lens. The control logic 1144 may control all operations of the camera module 1100b. For example, the control logic 1144 may control an operation of the camera module 1100b based on a control signal received through a control signal line CSLb

The memory 1146 may store information for the operation of the camera module 1100b, such as calibration data 1147. The calibration data 1147 may include information needed when the camera module 1100b generates image data using the light L. The calibration data 1147 may include, for example, information about a degree of rotation, information about a focal length, information about an optical axis, etc., as described above. When the camera module 1100b is implemented as a multi-state camera in which the focal length varies based on a position of the optical lens, the calibration data 1147 may include a focal length value based on each position (or each state) of the optical lens, and information related to auto focusing.

The storage 1150 may store image data sensed by the image sensor 1142. The storage 1150 may be disposed outside the image sensing device 1140, and may be stacked on a sensor chip that constitutes the image sensing device 1140. In some embodiments, the storage 1150 may be embodied as an Electrically Erasable Programmable Read-Only Memory (EEPROM). However, embodiments are not limited thereto

The storage 1150 may store image data sensed by the image sensor 1142. The storage 1150 may be disposed outside the image sensing device 1140, and may be stacked on a sensor chip that constitutes the image sensing device 1140. In some embodiments, the storage 1150 may be embodied as an EEPROM. However, embodiments are not limited thereto.

In one or more embodiments, each of the plurality of camera modules 1100a, 1100b, and 1100c may include the actuator 1130. Accordingly, each of the plurality of camera modules 1100a, 1100b, and 1100c may include the same or different calibration data 1147 based on an operation of the actuator 1130 included therein.

In one or more embodiments, one of the plurality of camera modules 1100a, 1100b, and 1100c, such as 1100b, may have a folded lens form that includes the prism 1105 and the OPFE 1110 as described above, while each of the remaining camera modules, such as 1100a and 1100c, may be a vertical-type camera module that does not include the prism 1105 and the OPFE 1110. However, embodiments are not limited thereto.

In some implementation, one of the plurality of camera modules 1100a, 1100b, and 1100c, such as 1100c, may be a vertical form depth camera that extracts depth information by using, for example, IR (infrared light). For example, the application processor 1200 may merge image data received from the depth camera and image data received from another camera module, such as 1100a or 1100b, to generate a three-dimensional (3D) depth image.

In one or more embodiments, at least two of the plurality of camera modules 1100a, 1100b, and 1100c, such as 1100a and 1100b, may have different Field of Views (FOVs). For example, optical lenses of at least two of the plurality of camera modules 1100a, 1100b, and 1100c, such as 1100a and 1100b, may differ from each other. However, embodiments are not limited thereto.

Further, in one or more embodiments, FOVs of each of the plurality of camera modules 1100a, 1100b, and 1100c may differ from each other. For example, the optical lenses in each of the plurality of camera modules 1100a, 1100b, and 1100c also may differ from each other. However, embodiments are not limited thereto.

In one or more embodiments, the plurality of camera modules 1100a, 1100b, and 1100c may be physically separated from each other.

For example, instead of a scheme in which a sensing area of one image sensor 1142 may be divided into a plurality of sub-areas that respectively correspond to the plurality of camera modules 1100a, 1100b, and 1100c, a scheme in which an individual image sensor 1142 may be disposed in each of the plurality of camera modules 1100a, 1100b, and 1100c is used.

Although embodiments have been described in detail with reference to the accompanying drawings, embodiments of the present disclosure are not necessarily limited thereto. Embodiments may take various forms within the scope while not departing from the technical idea of embodiments. Accordingly, embodiments disclosed in the present disclosure are not intended to limit the technical idea of the present disclosure, but to describe the present disclosure. The scope of the technical idea of embodiments of the present disclosure is not limited by the embodiments. Therefore, it should be understood that embodiments as described above are illustrative and non-limiting in all respects. The scope of protection of embodiments of the present disclosure should be interpreted by the claims, and all technical ideas within the scope of embodiments of the present disclosure should be interpreted as being included in the scope of embodiments of the present disclosure.

What is claimed is:

1. A depth sensor comprising:
a substrate comprising a first surface and a second surface that are opposite to each other;
a first pixel comprising a first photoelectric conversion element in the substrate; and
a second pixel adjacent to the first pixel, the second pixel comprising a second photoelectric conversion element in the substrate,
wherein the first pixel comprises a first tab and a second tab that are connected to the first photoelectric conversion element,
wherein the second pixel comprises a third tab connected to the second photoelectric conversion element,
wherein the second tab comprises a first floating diffusion region,
wherein the third tab comprises a second floating diffusion region, and
wherein a connection portion adjacent to the first surface of the substrate is between the first floating diffusion region and the second floating diffusion region.

2. The depth sensor of claim 1, further comprising a photoelectric conversion element isolation pattern in the substrate and between the first photoelectric conversion element and the second photoelectric conversion element,
wherein at least a portion of the connection portion overlaps the photoelectric conversion element isolation pattern along a vertical direction.

3. The depth sensor of claim 2, wherein the first floating diffusion region and the second floating diffusion region are on the first surface of the substrate, and
wherein the connection portion is on the first surface of the substrate.

4. The depth sensor of claim 3, wherein a portion of the connection portion is on the first floating diffusion region and the second floating diffusion region and contacts the first floating diffusion region and the second floating diffusion region.

5. The depth sensor of claim 2, wherein the first floating diffusion region and the second floating diffusion region are adjacent to the first surface of the substrate, and
wherein the connection portion is on a side surface of the first floating diffusion region and a side surface of the second floating diffusion region.

6. The depth sensor of claim 5, wherein the first surface of the substrate comprises a groove, and
wherein the connection portion is the groove.

7. The depth sensor of claim 6, wherein the connection portion has a cross shape from a top plan view of the first surface of the substrate.

8. The depth sensor of claim 7, wherein a width of the cross shape of the connection portion is equal to a width of the photoelectric conversion element isolation pattern in a horizontal direction.

9. The depth sensor of claim 1, wherein the first photoelectric conversion element is in a central region of the first pixel, and
wherein, from a top plan view of the first surface of the substrate, the first pixel has a rectangle shape,
wherein the second tab comprises a photo gate electrode, a tab transfer gate electrode, a storage gate electrode, a transfer gate electrode, and the first floating diffusion region in that order from the central region to a vertex of the rectangle shape of the first pixel, and
wherein the connection portion is at the vertex of the rectangle shape of the first pixel.

10. The depth sensor of claim 9, wherein the connection portion has a cross-shaped plane shape from the top plan view.

11. The depth sensor of claim 1, wherein the first tab comprises a third floating diffusion region,
wherein from a top plan view of the first surface of the substrate, the first pixel has a rectangle shape, and
wherein the first floating diffusion region and the third floating diffusion region are adjacent to a vertex of the rectangle shape of the first pixel.

12. The depth sensor of claim 1, wherein the first tab comprises a third floating diffusion region,
wherein the first pixel and the second pixel are adjacent to each other along a first horizontal direction, and
wherein the third floating diffusion region and the first floating diffusion region are adjacent to each other along the first horizontal direction.

13. The depth sensor of claim 1, wherein the first tab comprises a third floating diffusion region,
wherein the first pixel and the second pixel are adjacent to each other along a first direction, and
wherein the third floating diffusion region and the first floating diffusion region are spaced apart from each other in the first horizontal direction and a second horizontal direction perpendicular to the first horizontal direction.

14. A depth sensor comprising:
a substrate comprising a first surface and a second surface that are opposite to each other;
a first pixel comprising a first photoelectric conversion element in the substrate;
a second pixel adjacent to the first pixel, the second pixel comprising a second photoelectric conversion element in the substrate;
a photoelectric conversion element isolation pattern in the substrate and between the first photoelectric conversion element and the second photoelectric conversion element; and
a pad portion connected to the photoelectric conversion element isolation pattern,
wherein the first pixel comprises a first tab and a second tab that are connected to the first photoelectric conversion element,
wherein the second pixel comprises a third tab connected to the second photoelectric conversion element, and
wherein the first tab and the third tab share a floating diffusion region.

15. The depth sensor of claim 14, wherein the floating diffusion region is on the first surface of the substrate, and
wherein the pad portion is on the second surface of the substrate.

16. The depth sensor of claim 15, wherein the photoelectric conversion element isolation pattern comprises an insulating layer, and a doped polysilicon layer positioned in the insulating layer, and
wherein the pad portion is in contact with the polysilicon layer.

17. The depth sensor of claim 14, wherein the first pixel has a rectangle shape from a top plan view of the first surface of the substrate, and
wherein the floating diffusion region is adjacent to a vertex of the rectangle shape of the first pixel.

18. The depth sensor of claim 14, wherein the first pixel and the second pixel are adjacent to each other along a first horizontal direction, and
wherein the floating diffusion region of the first tab and the floating diffusion region of the second tab are adjacent to each other along the first horizontal direction.

19. The depth sensor of claim 14, wherein the first pixel and the second pixel are adjacent to each other along a first horizontal direction, and
wherein the floating diffusion region of the first tab and the floating diffusion region of the second tab are spaced apart from each other along the first horizontal direction and a second horizontal direction perpendicular to the first horizontal direction.

20. An electronic device comprising:
a camera comprising a depth sensor; and
an application processor configured to drive the camera,
wherein the depth sensor comprises:
a substrate comprising a first surface and a second surface that are opposite to each other;
a first pixel comprising a first photoelectric conversion element within the substrate; and
a second pixel in the substrate and adjacent to the first pixel, the second pixel comprising a second photoelectric conversion element,
wherein the first pixel comprises a first tab and a second tab connected to the first photoelectric conversion element,
wherein the second pixel comprises a third tab connected to the second photoelectric conversion element,
wherein the second tab comprises a first floating diffusion region,
wherein the third tab comprises a second floating diffusion region, and
wherein the first floating diffusion region and the second floating diffusion region are connected to each other.
